(19) United States
(12) Patent Application Publication
(10) Pub. No.: US 2019/0288662 A1
(43) Pub. Date: Sep. 19, 2019

(54) SURFACE ACOUSTIC WAVE DEVICES AND METHOD OF FABRICATING THE SAME

(71) Applicant: QUALCOMM Incorporated, San Diego, CA (US)

(72) Inventors: Bin Yang, San Diego, CA (US); Xia Li, San Diego, CA (US); Gengming Tao, San Diego, CA (US); Periannan Chidambaram, San Diego, CA (US)

(21) Appl. No.: 15/922,013

(22) Filed: Mar. 15, 2018

(51) Int. Cl. H03H 9/02; H03H 9/72; H03H 9/13; H03H 9/145; H03H 9/64

(52) U.S. Cl. CPC H03H 9/02661; H03H 9/02976; H03H 9/02574; H03H 9/6473; H03H 9/131; H03H 9/14517; H03H 9/72

(57) ABSTRACT

A surface acoustic wave (SAW) device comprises a substrate and composite electrodes. The composite electrodes comprise a metal layer and a graphene layer. The SAW device may be used to satisfy requirements for the fifth generation (5G) mobile communication.

### BACKGROUND

### Field

Certain aspects of the present disclosure generally relate to electronic devices, and more particularly, to surface acoustic wave devices.

### Background

Surface acoustic waves (SAWs) are essentially acoustic waves propagating on a surface of a substrate. The acoustic energy of SAWs is mostly confined near the surface of the substrate. In general, the substrate comprises piezoelectric materials, such as Zinc Oxide (ZnO), Aluminum Nitride (A1N), Lithium Tantalate (LiTaO₃), and Lithium Niobate (LiNbO₃). Electronic devices employing SAWs usually incorporate one or more interdigital transducers (IDTs) to convert electrical signals to acoustic waves and vice versa. When an alternating electrical signal is applied to the IDTs, the electrical field penetrates the surface of the piezoelectric substrate and SAWs are generated due to piezoelectric coupling.

SAW devices become widely used in the telecommunication industry in recent years. They can offer significant benefits in terms of performance, cost, and size over other competing technologies. SAW devices are considered to be a key component in many telecommunication systems, such as mobile phones, where they can provide a number of different functions.

One of the most common applications for the SAW devices in mobile phones is to use them as filters. As the mobile market moves from the fourth-generation long term evolution (4G LTE) to the fifth generation (5G), SAW filters continue to evolve to achieve better characteristics, such as higher operating frequency, wider bandwidth, smaller size, and lower insertion loss. However, unlike the 4G LTE, where SAW filters can work at frequencies below 2 gigahertz (GHz), for the 5G, SAW filters have to operate at frequencies between 3 GHz to 6 GHz. To date, the highest operating frequency reported for SAW filters is around 3.5 GHz. Thus, there is a need for SAW filters which can be used beyond 3.5 GHz.

### SUMMARY

Certain aspects of the present disclosure provide a surface acoustic wave (SAW) device. The SAW device may include a substrate and composite electrodes, wherein the composite electrodes may include a first metal layer on the substrate and a graphene layer on the first metal layer.

Certain aspects of the present disclosure provide a method for fabricating a SAW device. The method may include forming a first metal layer on a substrate. The method may also include forming a graphene layer on the first metal layer. The method may further include patterning the first metal layer and the graphene layer.

This summary has outlined, rather broadly, the features and embodiments of the present disclosure so that the following detailed description may be better understood. Additional features and embodiments of the present disclosure will be described below. It should be appreciated by those skilled in the art that this disclosure may be readily utilized as a basis for modifying or designing other equivalent structures for carrying out the same purposes of the present disclosure. It should also be realized by those skilled in the art that such equivalent constructions do not depart from the teachings of the present disclosure as set forth in the appended claims. The features, which are believed to be characteristic of the present disclosure, both as to its organization and method of operation, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1 illustrates an exemplary fabrication process for a surface acoustic wave (SAW) device, where cross-sectional diagrams for respective stages of the fabrication process are provided;

FIG. 2 is an exemplary SAW device having composite electrodes in accordance with certain aspects of the present disclosure;

FIG. 3 provides a flow chart illustrating an exemplary fabrication process for the SAW device of FIG. 2 in accordance with certain aspects of the present disclosure;

FIG. 4 provides cross-sectional diagrams of the SAW device of FIG. 2 at each stage of the process of fabrication in FIG. 3; and

FIG. 5 is a block diagram showing an exemplary wireless communication system in which an aspect of the present disclosure may be employed.

### DETAILED DESCRIPTION

With reference to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

The detailed description set forth below, in connection with the appended drawings, is intended as a description of various aspects and is not intended to represent the only aspect in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts.

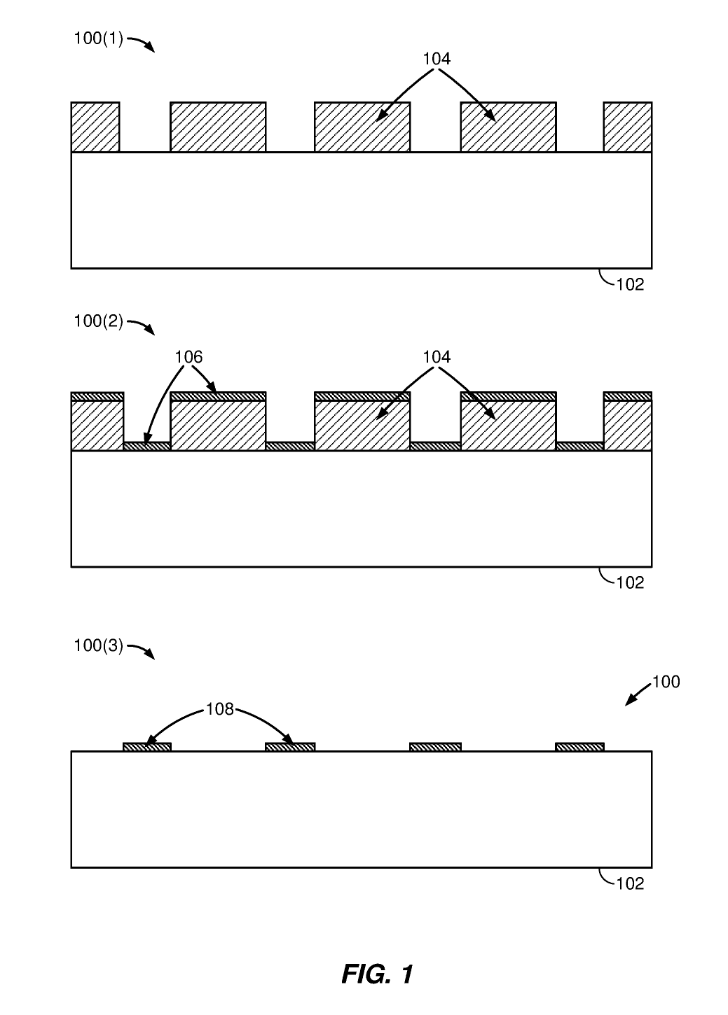

FIG. 1 illustrates an exemplary fabrication process for a surface acoustic wave (SAW) device 100, where cross-sectional diagrams for respective stages 100(1)-100(3) of the fabrication process are provided. In this regard, the fabrication process includes forming a photoresist layer 104 on a substrate 102 and patterning the photoresist layer 104 (stage 100(1)). The substrate 102 may comprise piezoelectric materials, such as Lithium Niobate (LiNbO₃). The fabrication process further includes depositing an electrode layer 106 on the photoresist layer 104 and the substrate 102 (stage 100(2)). The electrode layer 106 may comprise metals, such as Aluminum (Al) and Gold (Au). Next, the fabrication process includes removing the photoresist layer 104 and forming electrodes 108 on the substrate 102 (stage 100(3)). The photoresist layer 104 may be removed by lift off process. The electrodes 108 may comprise interdigital transducers (IDTs). IDTs may comprise two or more interlocking comb shape arrays of metallic electrodes.

A resonant frequency of the SAW device 100 may be determined by v/λ, where v is a velocity of the SAW and λ is a wavelength of the SAW. The wavelength of the SAW (λ) may be determined based on a periodicity of the IDTs, where one half of λ may be equal to a period of the IDTs. Thus, as the resonant frequency of the SAW device 100 continues to increase, the wavelength of the SAW (λ) becomes smaller, which requires continuous shrinking of the period of the IDTs. The period of the IDTs may be defined by a limitation of photo lithography process. As the period of the IDTs becomes smaller, more complex and expensive photo lithography processes have to be employed to fabricate the SAW device 100.

Meanwhile, the IDTs on the SAW device 100 have a mass loading effect which may lower the velocity of the SAW (v), resulting in a decrease in the resonant frequency of the SAW device 100. The mass loading effect may relate to a weight of the IDTs. As the weight of the IDTs increases, the mass loading effect becomes more severe, resulting in larger decrease in the resonant frequency of the SAW device 100. As the weight of the IDTs decreases, the mass loading effect becomes less severe, resulting in smaller decrease in the resonant frequency of the SAW device 100. Thus, to realize high resonant frequency for the SAW device 100, it is beneficial to choose materials with less weight (i.e., low density) to form the IDTs. Another factor to consider when selecting IDT materials is conductivity. High conductivity means less resistive loss from the IDTs, which may translate into a high quality factor (Q) of the SAW device 100. Therefore, by selecting the IDT materials with low density and high conductivity, the resonant frequency and Q of the SAW device 100 can be improved. Common IDT materials used for the SAW device 100 are Al and Au. Al has a density of 2.7 g/cm³ and a conductivity of 3.5×10⁷ S/m. Au has a density of 19.32 g/cm³ and a conductivity of 4.1×10⁷ S/m. To improve the resonant frequency and Q of the SAW device 100, an IDT material with a density lower than Al and a conductivity higher than Au may be employed.

Graphene is a form of carbon which comprises a single layer of carbon atom arranged in a hexagonal lattice. Graphene has been reported with a density of 1.2 g/cm³ and a conductivity of 1×10⁸ S/m. Thus, graphene satisfies requirements above for the IDT materials of the SAW device 100. For example, for a given set of dimensions, graphene IDTs would have a smaller weight compared to Al IDTs or Au IDTs, resulting in a smaller mass loading effect. With a same conductivity of the IDTs, when the period of the IDTs is constant, a thickness of graphene IDTs would be smaller compared to a thickness of Al IDTs or a thickness of Au IDTs. Combining the low density and high conductivity of graphene, the mass loading effect can be reduced without compromise on the Q of the SAW device 100 when graphene IDTs are used. Thus, for a similar Q, the SAW device 100 using graphene IDTs would have a higher resonant frequency compared to the SAW device 100 with Al IDTs or Au IDTs. The current highest resonant frequency reported for a SAW device is 3.5 gigahertz (GHz) using Al IDTs. Therefore, by adopting graphene as IDT materials, the resonant frequency of the SAW device 100 could be extended beyond 3.5 GHz, which can satisfy requirements for the fifth generation (5G) mobile communication.

Aspects disclosed in the detailed description include a SAW device with composite electrodes to extend a resonant frequency of the SAW device beyond 3.5 GHz. In certain aspects, a SAW device comprises a substrate and composite electrodes on the substrate. The composite electrodes may comprise a first metal layer on the substrate and a graphene layer on the first metal layer. The composite electrodes may further comprise a second metal layer on the graphene layer. As mentioned above, the introduction of the graphene layer may alleviate the mass loading effect without compromise on a Q of the SAW device. Therefore, the SAW device with the composite electrodes can be used to satisfy the requirements for the 5G mobile communication.

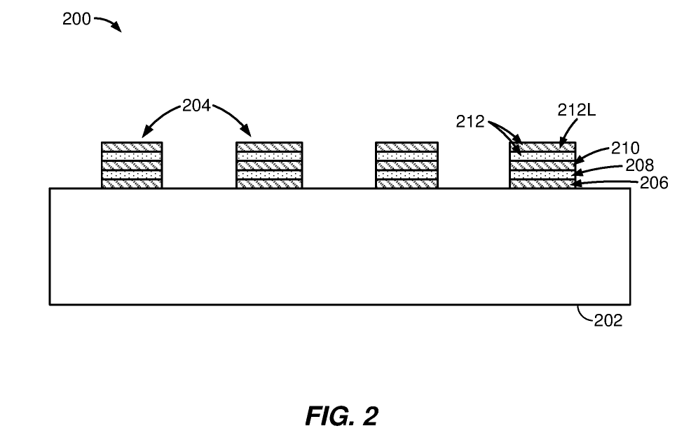

In this regard, FIG. 2 illustrates an exemplary SAW device having composite electrodes in accordance with certain aspects of the present disclosure. A SAW device 200 is shown in FIG. 2, which comprises a substrate 202 and composite electrodes 204 on the substrate 202. As an example, the substrate 202 may comprise piezoelectric materials, such as LiNbO₃. The composite electrodes 204 comprise a first metal layer 206 on the substrate 202 and a graphene layer 208 on the first metal layer 206. The composite electrodes 204 may further comprise a second metal layer 210 on the graphene layer 208. The composite electrodes 204 may further comprise additional alternating graphene and metal layers 212 on the second metal layer 210. A last layer of the additional alternating graphene and metal layers 212 may comprise a metal layer 212L. The first metal layer 206, the second metal layer 210, and the additional metal layers may comprise Al or Au. As mentioned above, due to the low density and high conductivity of graphene, the composite electrodes 204 may alleviate the mass loading effect without compromise on a Q of the SAW device 200. Therefore, a resonant frequency of the SAW device 200 can be improved.

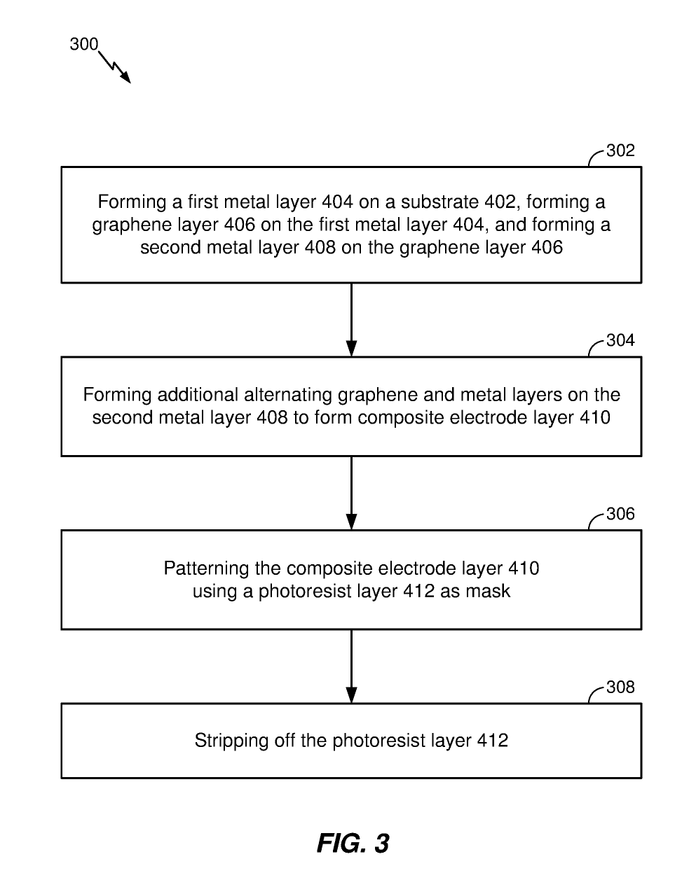

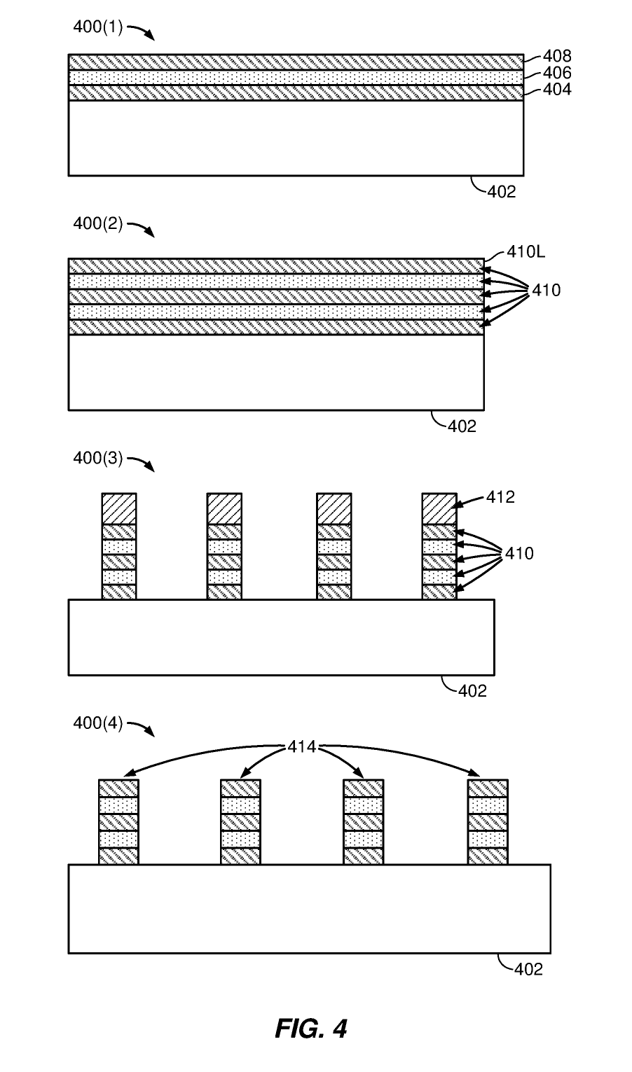

FIG. 3 illustrates an exemplary fabrication process 300 for the SAW device 200 in FIG. 2 in accordance with certain aspects of the present disclosure. FIG. 4 provides cross-sectional diagrams of the SAW device 200 of FIG. 2 illustrating respective stages 400(1)-400(4) of the fabrication process 300 in FIG. 3. The cross-sectional diagrams illustrating the SAW device 200 in FIG. 4 will be discussed in conjunction with the discussion of the exemplary steps in the fabrication process 300 in FIG. 3.

In this regard, the fabrication process 300 in FIG. 3 includes forming a first metal layer 404 on a substrate 402, forming a graphene layer 406 on the first metal layer 404, and forming a second metal layer 408 on the graphene layer 406 (block 302, stage 400(1) of FIG. 4). As an example, the substrate 402 may comprise piezoelectric materials, such as LiNbO₃. The first metal layer 404 and the second metal layer 408 may comprise Al or Au. The first metal layer 404 and the second metal layer 408 may each comprise one monolayer formed by atomic layer deposition (ALD). The graphene layer 406 may comprise one monolayer formed by ALD.

The fabrication process 300 in FIG. 3 also includes forming additional alternating graphene and metal layers on the second metal layer 408 to form composite electrode layer 410 (block 304, stage 400(2) of FIG. 4). As an example, the additional metal layers may comprise Al or Au. Each of the additional metal layers may comprise one monolayer formed by ALD. Each of the additional graphene layers may comprise one monolayer formed by ALD. A number of layers in the composite electrode layer 410 may be determined based on requirements for the resonant frequency and Q of the SAW device 200. A last layer of the composite electrode layer 410 may comprise a metal layer 410L.

The fabrication process 300 in FIG. 3 further includes patterning the composite electrode layer 410 (block 306, stage 400(3) of FIG. 4). As an example, the composite electrode layer 410 may be patterned through photo lithography and dry etching using a photoresist layer 412 as mask. The dry etching may stop on the substrate 402.

Next, the fabrication process 300 in FIG. 3 includes stripping off the photoresist layer 412 (block 308, stage 400(4) of FIG. 4). After stripping off the photoresist layer 412, the SAW device 200 comprising the substrate 402 and composite electrodes 414 is completed. As mentioned above, the composite electrodes 414 may alleviate the mass loading effect without compromise on the Q of the SAW device 200, which may be used to satisfy the requirements for the 5G mobile communication.

The elements described herein are sometimes referred to as means for performing particular functions. In this regard, the substrate 202 is sometimes referred to herein as “means for providing piezoelectric coupling.” The composite electrodes 204 are sometimes referred to herein as “means for generating surface acoustic waves.” According to a further aspect of the present disclosure, the aforementioned means may be any layer, module, or any apparatus configured to perform the functions recited by the aforementioned means.

The SAW device comprising the composite electrodes according to certain aspects disclosed herein may be provided in or integrated into any electronic device. Examples, without limitation, include a set top box, an entertainment unit, a navigation device, a communication device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, and a drone.

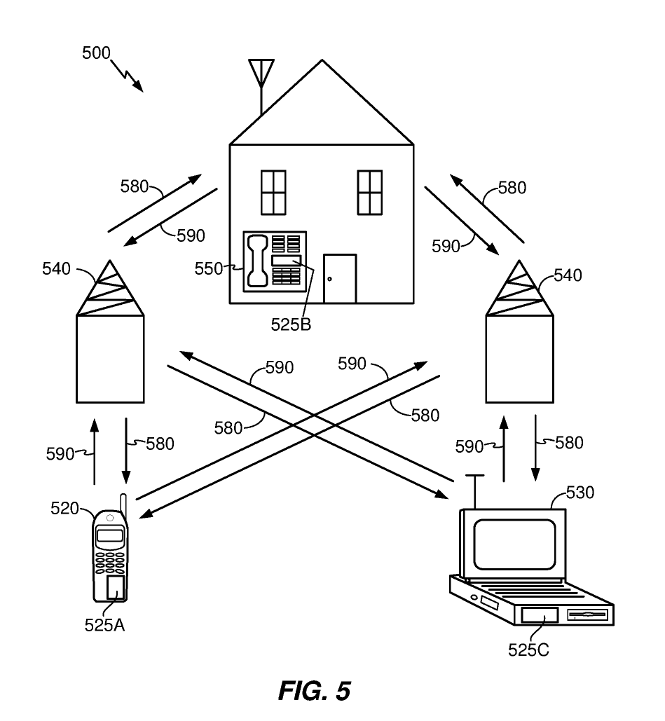

In this regard, FIG. 5 is a block diagram showing an exemplary wireless communication system 500 in which an aspect of the present disclosure may be employed. For purposes of illustration, FIG. 5 shows three remote units 520, 530, and 550 and two base stations 540. It will be recognized that wireless communication systems may have many more remote units and base stations. Remote units 520, 530, and 550 include integrated circuit (IC) devices 525A, 525C, and 525B that may include the disclosed SAW device. It will be recognized that other devices may also include the disclosed SAW device, such as the base stations, switching devices, and network equipment. FIG. 5 shows forward link signals 580 from the base stations 540 to the remote units 520, 530, and 550 and reverse link signals 590 from the remote units 520, 530, and 550 to the base stations 540.

In FIG. 5, remote unit 520 is shown as a mobile telephone, remote unit 530 is shown as a portable computer, and remote unit 550 is shown as a fixed location remote unit in a wireless local loop system. For example, a remote unit may be a mobile phone, a hand-held personal communication systems (PCS) unit, a portable data unit such as a PDA, a GPS enabled device, a navigation device, a set top box, a music player, a video player, an entertainment unit, a fixed location data unit, such as a meter reading equipment, or other communication device that stores or retrieves data or computer instructions, or combinations thereof. Although FIG. 5 illustrates remote units according to the certain aspects of the present disclosure, the disclosure is not limited to these exemplary illustrated units. Certain aspects of the present disclosure may be suitably employed in many devices, which include the disclosed SAW device.

Those of skill in the art will further appreciate that the various illustrative logical blocks, modules, circuits, and algorithms described in connection with the certain aspects disclosed herein may be implemented as electronic hardware, instructions stored in memory or in another computer readable medium and executed by a processor or other processing device, or combinations of both. The devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the certain aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and features disclosed herein.

What is claimed is:

1. A surface acoustic wave (SAW) device, comprising a substrate and composite electrodes, wherein the composite electrodes comprise a first metal layer on the substrate and a graphene layer on the first metal layer.

2. The SAW device of claim 1, wherein the composite electrodes further comprise a second metal layer on the graphene layer.

3. The SAW device of claim 1, wherein the substrate comprises piezoelectric materials.

4. The SAW device of claim 3, wherein the piezoelectric materials comprise Lithium Niobate (LiNbO₃).

5. The SAW device of claim 2, wherein the first metal layer and the second metal layer comprise at least one of Aluminum (Al) and Gold (Au).

6. The SAW device of claim 2, wherein the composite electrodes further comprise alternating graphene and metal layers on the second metal layer.

7. The SAW device of claim 6, wherein a last layer of the alternating graphene and metal layers is a metal layer.

8. The SAW device of claim 6, wherein metal layers in the alternating graphene and metal layers comprise at least one of Al and Au.

9. The SAW device of claim 2, wherein the first metal layer and the second metal layer are monolayers.

10. The SAW device of claim 1, wherein the graphene layer is a monolayer.

11. The SAW device of claim 6, wherein each layer of the alternating graphene and metal layers is a monolayer.

12. The SAW device of claim 1 integrated into a device selected from the group consisting of: a set top box; an entertainment unit; a navigation device; a communication device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; and a drone.

13. A method for fabricating a surface acoustic wave (SAW) device, comprising:
forming a first metal layer on a substrate;
forming a graphene layer on the first metal layer; and
patterning the first metal layer and the graphene layer.

14. The method of claim 13, further comprising forming a second metal layer on the graphene layer and patterning the second metal layer.

15. The method of claim 14, further comprising forming alternating graphene and metal layers on the second metal layer and patterning the alternating graphene and metal layers.

16. The method of claim 15, wherein a last layer of the alternating graphene and metal layers is a metal layer.

17. The method of claim 14, wherein the first metal layer and the second metal layer comprise at least one of Aluminum (Al) and Gold (Au).

18. The method of claim 14, wherein the first metal layer and the second metal layer are monolayers.

19. The method of claim 18, wherein the forming the first metal layer on the substrate comprises forming the first metal layer on the substrate by atomic layer deposition (ALD), and wherein the forming the second metal layer on the graphene layer comprises forming the second metal layer on the graphene layer by ALD.

20. The method of claim 13, wherein the graphene layer is a monolayer.

21. The method of claim 20, wherein the forming the graphene layer on the first metal layer comprises forming the graphene layer on the first metal layer by ALD.

22. The method of claim 15, wherein metal layers in the alternating graphene and metal layers comprise at least one of Al and Au.

23. The method of claim 13, wherein the substrate comprises piezoelectric materials.

24. The method of claim 23, wherein the piezoelectric materials comprise Lithium Niobate (LiNbO₃).

25. The method of claim 15, wherein each layer of the alternating graphene and metal layers is a monolayer.
